(19) United States
(12) Patent Application Publication
(10) Pub. No.: US 2025/0204281 A1
(43) Pub. Date: Jun. 19, 2025

(54) PROCESS FOR LOW-LOSS DIELECTRIC AND RELATED STRUCTURES

(71) Applicant: Massachusetts Institute of Technology, Cambridge, MA (US)

(72) Inventors: William D. Oliver, Lexington, MA (US); Alexander J. Melville, Chelmsford, MA (US); Wayne H. Woods, Carlisle, MA (US); Jonilyn L. Yoder, Billerica, MA (US); Sergey K. Tolpygo, Waltham, MA (US); Mollie E. Schwartz, Belmont, MA (US); Evan B. Golden, Andover, MA (US); David K. Kim, Concord, MA (US); Kyle A. Serniak, Somerville, MA (US); Bethany Niedzielski Huffman, Chelmsford, MA (US); Arjan Sevi, West Roxbury, MA (US)

(73) Assignee: Massachusetts Institute of Technology, Cambridge, MA (US)

(21) Appl. No.: 18/842,858

(22) PCT Filed: Jan. 9, 2023
(86) PCT No.: PCT/US2023/010399

§ 371 Date: Aug. 30, 2024

Related U.S. Application Data
(60) Provisional application No. 63/318,142, filed on Mar. 9, 2022.

(51) Int. Cl. H10N 69/00; H01G 4/008; H01G 4/10; H10N 60/12

(52) U.S. Cl. CPC H10N 69/00; H01G 4/008; H01G 4/10; H10N 60/12

(57) ABSTRACT

Described are a method for providing a low loss dielectric and related structures and devices comprising such a low loss dielectric. The method and low loss dielectric are suitable for use in superconducting devices, circuits and systems as well as in superconducting quantum devices, circuits and systems. In embodiments, a shadow-evaporation technique is used to provide a parallel-plate superconducting capacitor having an aluminum oxide dielectric.

### GOVERNMENT RIGHTS

This invention was made with government support under FA8702-15-D-0001 awarded by the U.S. Air Force. The government has certain rights in the invention.

### BACKGROUND

As is known in the art, capacitors are an integral component in many superconducting devices, including but not limited to microwave kinetic inductance detectors, traveling-wave parametric amplifiers, many types of superconducting qubits, e.g., flux qubits, transmons, for gate-based quantum computers. These capacitors may be provided as coplanar capacitors or as parallel-plate capacitors, e.g., trilayer parallel-plate capacitors.

As also known, the dielectric losses associated with the time-varying electric field in the capacitors are a significant limitation to the device performance in all applications, especially the performance of quantum devices. That is, performance of superconducting quantum devices suffers from lossy dielectric materials or defects found at metal-dielectric interfaces, interfaces of non-metal layers, and inside the dielectric. In some superconducting quantum devices, loss may be reduced (and ideally minimized) by carefully designing the superconducting quantum device to avoid concentrating electric field energy in regions of lossy dielectrics.

Many superconducting devices employ co-planar capacitors since coplanar capacitors typically have the lowest loss (loss tangent tan δ) with a single-photon quality factor (Q_{sp,i}=1/tan δ) of about 1 million (1M). Unfortunately, the capacitance per area (or, specific capacitance, C_{S}) of coplanar capacitors (CPCs) is significantly lower than that of parallel-plate capacitors (PPCs). This is because the distance between electrodes in CPCs is on order microns compared to nanometers in PPCs. Thus, as superconducting devices (e.g., superconducting quantum devices) increase in complexity and integration scale, CPCs may no longer provide sufficient capacitance, e.g., for zero-pi qubits that require multiple capacitors with more than 1 pF capacitance, or may limit the total number of qubits that can fit on an integrated circuit (i.e., a chip), e.g., for a quantum annealer requiring thousands of qubits.

Several approaches to increasing the effective device specific capacitance C_{S} exist, such as using three-dimensional (3D) integrated processing, merging a shunt capacitor with a low-loss Josephson Junction (JJ), and using PPCs based upon low-loss dielectrics, e.g., dielectrics having a dielectric loss tangent (tan δ) in the range of about 10⁻⁴ to about 10⁻⁶ such as silicon nitride, hexagonal boron nitride, and crystalline silicon. However, a need still exists for a reproducible, scalable process for fabricating highly uniform, high specific capacitance C_{S}, low-loss PPCs.

### SUMMARY OF DISCLOSED EMBODIMENTS

In accordance with one aspect of the concepts sought to be protected, described herein are methods to provide a low loss, clean, and high purity dielectric.

In accordance with a further aspect of the concepts sought to be protected, also described are methods that enable a clean and high purity dielectric to be provided between two capacitor electrodes.

In accordance with a still further aspect of the concepts sought to be protected, described herein are devices, circuits, systems, and methods to make a shadow-evaporated parallel-plate superconducting capacitor using an aluminum oxide dielectric. It should be appreciated that described methods are not limited to any single type of shadow evaporation technique (e.g., Dolan bridge, Manhattan, Lecocq).

In embodiments, capacitors provided in accordance with the concepts described herein comprise two superconducting aluminum layers separated by a ow-loss aluminum oxide dielectric having a selectable (or tunable) thickness, where the dielectric is fabricated by oxidizing a first (or bottom) electrode and the thickness is tuned by adding (e.g. depositing) one or more layers (e.g., up to N layers, where N is an integer) of thin (<0.5 nm) aluminum which are individually and sequentially oxidized before depositing a second (or top) electrode. In embodiments, the individually oxidized aluminum layers are provided as individually oxidized thin aluminum layers (e.g., layers having a thickness less than 0.5 nm).

Although one use of the described materials and methods is as a low-loss, high capacitance density capacitor, it should be appreciated that the described materials and concepts may have applications as a non-linear inductor depending upon the thickness of the dielectric.

The concepts, systems, devices structures, and techniques describe herein are thus applicable to the field of superconducting quantum circuits, as a circuit element (capacitor) that provides higher capacitance density and/or lower dielectric loss (loss tangent) than the prior art alternatives such as coplanar capacitors and trilayer parallel-plate capacitors.

In embodiments, the described concepts, systems, devices structures, and techniques may be used to provide a dielectric having a low dielectric loss tangent (tan δ<1E-4). Such a dielectric can be used to provide a parallel-plate capacitor in a superconducting quantum circuit. In some circuits and systems, use of dielectrics having a low dielectric loss tangent may be required to satisfy system requirements. In some embodiments, dielectrics having a low dielectric loss tangent in the range of about tan δ<5E-3 (e.g., for some applications like traveling-wave parametric amplifiers or TWPAs) to about tan δ<1E-5 (e.g., for gate-based superconducting qubits). In embodiments, parallel-plate capacitors provided in accordance with the concepts and techniques described herein may be as much as 100× less lossy than comparable superconducting parallel-plate capacitors used in TWPAs, and there is no comparable parallel-plate capacitor for the state-of-the-art superconducting qubits. And, although the dielectric loss may be in the range or about 10× to about 100× higher than in the coplanar capacitor alternative, advantages of a parallel-plate capacitor include but are not limited to: (1) the reduced cross-talk between devices (e.g., qubits); (2) reduced (and ideally minimal) interaction with the environment compared with conventional superconducting parallel-plate capacitors; and (3) up to a 100× reduction in device size due to the significantly higher capacitance density (capacitance per unit area, e.g., measured in fF/μm²).

The concepts described herein, may therefore, be used to improve the performance in TWPAs due to the lower loss, and address problems related to increasing circuit size, complexity, and scaling-up issues in superconducting qubits by providing an acceptably low-loss capacitor with significantly higher capacitance density (fF/μm²).

Quantum circuit applications that currently rely on coplanar capacitors for the ultimate low-loss dielectrics, like superconducting qubits, would benefit most from the increase in the capacitance density. For example, the use of capacitors provided in accordance with the concepts described herein would enable scaling-up the device number areal density by a factor in the range of about 10× to about 100×.

Quantum circuit applications, like TWPAs, that rely on existing parallel-plate capacitors would directly benefit from the reduction in the loss as a system's performance increase. However, it should also be appreciated that the concepts and low-loss parallel-plate capacitors described herein may be used in any quantum circuit devices, systems, and applications requiring both a low-loss dielectric and a high capacitance density. Such devices include but are not limited to: photon detectors, isolators (including on-chip isolators).

The concepts described herein encompass both devices and methods. In one aspect, the concepts are directed toward a method to make a shadow-evaporated parallel-plate superconducting capacitor using an aluminum oxide dielectric. One important aspect of such a device is its use as a low-loss, high capacitance density capacitor.

However, the concepts devices and methods described herein may have some applications as a non-linear inductor depending on the thickness of the dielectric. It is defined by two superconducting aluminum layers separated by a tunably thick low-loss aluminum oxide dielectric.

One feature of the concepts devices and methods described is the use of a very thin (e.g., 5-15 nm) dielectric as a capacitor. Such capacitors are well-suited for use in circuits and systems having low power requirements. For example, capacitors provided in accordance with the concepts and methods described herein are suitable for use in experiments in a dilution refrigerator such that the breakdown voltage is not exceeded. It is noted that devices, circuits and systems provided using the methods described herein could generate some pseudo-Josephson inductance due to the very thin dielectric, but in the applications discussed, the inductance is dominated by Josephson junctions, and the additional inductance from devices, circuits and systems provided using the methods described herein would be small in comparison and is simply another design input with minimal deleterious effects in the device.

Another feature of the concepts devices and methods described is the process by which the dielectric is formed. Use of the methods described herein results in a dielectric having a low-loss characteristic (or property) and enables the dielectric to have a selectable (or tunable) thickness.

Devices fabricated in accordance with the concepts described herein can be discovered in several ways. First, the dielectric can be identified using any number of common characterization techniques, e.g., transmission electron microscopy (TEM) combined with electron energy loss spectroscopy (EELS) or secondary-ion mass spectrometry (SIMS). Second, the use of shadow evaporation can be detected using a scanning electron microscope (SEM), since shadow evaporation leaves a telltale overlap of identical patterns from its numerous angled depositions. Third, its use as a capacitive element can be determined from the circuit design, or by analysis of the device using SEM.

The concepts described herein have a wide range of applications, since the concepts and techniques described herein may be used to fabricate basic circuit elements.

In one aspect, one advantage of the concepts, device and techniques described herein is the low-loss dielectric in the capacitor, as defined by the loss tangent of the dielectric. The loss tangent is about 10× lower than comparable parallel-plate capacitors and is the key feature that enables its use in superconducting circuits. The primary limitation is that the loss tangent is still about 100× higher than that in coplanar capacitors, such that a design choice must be made between highest performance (lowest loss tangent) and highest device density (highest specific capacitance). Further materials development may further reduce the loss tangent, in which case there would be no reason not to choose this invention.

In one aspect, described is a process for making superconductor-insulator-superconductor devices, where the insulator is low-loss and can be made thick from 2 nm to 20 nm thick.

In one aspect, devices may be defined by a low-loss dielectric fabrication process based upon repetitive deposition and oxidation of metal to form the dielectric (insulator).

In one aspect, the concepts described herein may be used to provide high-density, low-loss capacitors and inductors for use in noise-sensitive microwave and millimeter wave (MMW) superconducting circuits including, but not limited to: Qubit capacitor; Gate-based quantum computing, e.g., transmons; Quantum annealing, e.g., flux qubits; capacitor or inductor in lumped element resonator; readout and control of superconducting qubits; construction of photon detectors, e.g. transition-edge sensors; construction of devices based on traveling-wave propagation (directional devices); and coupling capacitor or inductor between microwave components.

In embodiments, the concepts described may be used to provide a low-loss parallel-plate capacitor (PPC) (Q˜40,000) having a specific capacitance (C_{S}) of about 10 fF μm⁻² using an aluminum oxide dielectric having a “tunable” thickness. In embodiments the thickness of the aluminum oxide dielectric is in the range from about 2 nm to about 10 nm.

Further, in accordance with the techniques described herein such PPCs may be uniformly fabricated. Such a PPC may be used in devices including, but not limited to, lumped-element resonators (Q˜40,000), flux qubits and transmons (with coherence time T₁˜3-30 μs), and traveling-wave parametric amplifiers. Performance results of such devices are consistent with the use of a dielectric having a loss tangent tan δ in the range from about 10⁻⁴ to about 10⁻⁵. Such results depend upon applied power and time scale of the measurement.

Based upon these results, a PPC provided in accordance with the concepts described herein is an effective alternative to coplanar capacitors for use in quantum circuits. Further, use of PPCs provided in accordance with the concepts described herein enables scaling-up and fabrication of complex quantum devices and circuits. In short, PPCs fabricated or otherwise provided in accordance with the concepts described herein are on the order of about a 100× smaller while only about 10× more lossy than coplanar capacitors, and may be constructed or otherwise fabricated or provided using a reproducibly uniform fabrication processes compatible with existing superconducting quantum devices.

In accordance with another aspect, a shadow-evaporated parallel-plate superconducting capacitor comprises the first and second layers of superconducting material and an aluminum oxide dielectric having a thickness selected to provide the parallel-plate superconducting capacitor having a desired performance characteristic.

In embodiments, the shadow-evaporated parallel-plate superconducting capacitor includes the first (the bottom) electrode layer and a dielectric fabricated by oxidizing at least portions of the first superconducting layer and the dielectric thickness is tuned by adding N layers of individually oxidized aluminum (where N is an integer greater than or equal to 1) before fabricating the top superconducting electrode.

In embodiments the N layers of individually oxidized thin aluminum are provided having a thickness of less than one-half nanometer (<0.5 nm).

In embodiments, the aluminum oxide dielectric is a tunable-thickness low-loss aluminum oxide dielectric, where the dielectric is fabricated by oxidizing at least portions of at least one of the first and second layers of superconducting material.

In accordance with a still further aspect of the concepts described herein, a method for forming a superconducting structure comprises disposing a first electrode over a first surface of a substrate and using a shadow-evaporated process to form one or more layers of an aluminum oxide dielectric over the first electrode and forming a second electrode over the one or more layers of aluminum oxide dielectric.

In embodiments, the shadow evaporation comprises at least one of: a Dolan bridge type; a Manhattan type; and a Lecocq type.

In embodiments, the aluminum oxide dielectric is fabricated by oxidizing the bottom electrode and the thickness of the aluminum oxide dielectric is tuned by adding N layers of individually oxidized aluminum before fabricating the second electrode.

In embodiments, wherein the first and second electrodes are provided from first and second layers of superconducting material and the method comprises fabricating a tunably thick low-loss aluminum oxide dielectric by oxidizing at least portions of at least one of the first and second layers of superconducting material and adding N layers of individually oxidized thin aluminum wherein N is an integer greater than or equal to one to provide the aluminum oxide dielectric having a desired thickness.

In accordance with a still further aspect of the concepts described herein, A superconducting device includes first and second layers of superconducting material; and a dielectric disposed between and in contact with the first and second layers of superconducting material, the dielectric comprising N individual layers of an oxidized metal with each of the N individual layers of oxidized metal having a sub-nanometer thickness wherein N is an integer greater than or equal to one.

In embodiments, the oxidized metal may be provided as oxidized aluminum.

In embodiments, the oxidized metal is provided having a thickness of less than one-half nanometer

### DESCRIPTION OF THE SEVERAL VIEWS OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principals of the concepts described herein. Like reference numerals designate corresponding parts throughout the different views. Furthermore, embodiments are illustrated by way of example and not limitation in the figures, in which:

FIGS. 1A-1C are a series of views illustrating a deposition process at two different deposition angles;

FIG. 2 is an image of a shadow-evaporated parallel-plate superconducting capacitor;

FIG. 3 is a flow diagram of a process for fabricating a shadow-evaporated device for use in superconducting circuit;

FIG. 4 is a process flow chart of an illustrative minimum process;

FIG. 5 is a process flow chart of an illustrative a single lithographic process;

FIG. 6 is a process flow chart of an illustrative a double lithographic process;

FIGS. 7A-7B are a series of images illustrating different types of shadow evaporation (Dolan bridge, Manhattan, Lecocq);

FIG. 8A is a schematic;

FIG. 8B is an enlarged view of a portion of FIG. 8A;

FIG. 8C is a plot of internal quality factor vs. Number of circulating photons;

FIG. 9A is an image;

FIG. 9B is an enlarged view of a portion of FIG. 9A;

FIG. 9C is a plot of insertion loss; and

FIGS. 10A-10C are a series of views showing capacitors.

### DETAILED DESCRIPTION

Before describing the broad concepts, devices, systems and techniques sought to be protected herein, some introductory concepts are explained.

In one aspect, described is the use of aluminum oxide (AlOₓ) as a dielectric for a low-loss parallel-plate capacitor (PPC) having a high specific capacitance C_{S}. Although aluminum oxide is quite lossy (e.g., a dielectric loss tangent tan δ is about 10⁻³), this dielectric is commonly used in Josephson Junctions (JJs) whose loss is estimated to be orders of magnitude lower (tan δ in the range from about 10⁻⁴ to about 10⁻⁸). This can be accomplished by reducing the total dielectric volume below some threshold where there is no longer a continuous distribution of two-level systems (TLS), but rather only a countably few TLS, on order from about 200 to about 500 GHz⁻¹μm⁻³ in a typical amorphous aluminum oxide.

Similarly, a low-dielectric-volume aluminum oxide capacitor may have a much lower effective loss, on par with that observed in JJs, while also achieving a very high C_{S} by balancing the dielectric thickness such that it is thick enough to suppress Josephson tunneling and thin enough to maximize C_{S}.

Also, described herein is the fabrication of such low-loss, high C_{S} PPCs (LLPPC) with a tunable-thickness dielectric material (e.g., aluminum oxide dielectric). That is, a thickness of the dielectric may be selectable (i.e., the dielectric is provided having a desired thickness selected to suit the needs of a particular application and result in a device having desirable electrical and/or mechanical characteristics). This may be accomplished using a shadow-evaporated process. In the case of the dielectric being an aluminum oxide dielectric, the thickness of the dielectric may be in the range from about 1 nm to about 20 nm (or more, depending on the desired specific capacitance) or preferably in the range from about 5 to about 10 nm.

In one embodiment, the LLPPC capacitance and process uniformity across a chip and a 50-mm-diameter wafer were characterized. Also, characterized were the dielectric loss in LLPPC in lumped-element (LE) resonators, traveling-wave parametric amplifiers (TWPA), capacitively-shunted qubits, and in couplers between qubits, resonators, and feedlines.

The LLPPC fabrication is compatible with any qubit process. Thus, it should be appreciated the description provided herein with reference to certain processes and devices completed on 50 mm high-resistivity silicon substrates is for example only. After reading the disclosure provided herein, those of ordinary skill in the art will appreciate that the concepts and processes described may be used with other types of substrates with appropriate processing modifications to provide a wide variety of different devices which embody the concepts described herein. After reading the disclosure provided herein, such modifications are within the skill of one of ordinary skill in the art.

The LLPPC has been fabricated with many additive shadow-evaporation techniques, including the Dolan-bridge process, a Manhattan-style process, and a Lecocq process. Subtractive processes may also be used to create AlOₓ capacitors, by growing the dielectric first and then etching. However, the subtractive approach involves more fabrication steps and therefore may, although not necessarily, lead to more loss. Any other additive technique, including by not limited to aluminum deposition by magnetron sputtering, electron beam evaporation, and thermal evaporation, can be used. In some embodiments, the structure can be defined by electron-beam lithography (although photolithography could be employed). An evaporator, examples include, but are not limited to those made by manufacturers such as Plassys, Angstrom, etc., in a single-chamber, multi-chamber, cluster tool, or other configurations, can then be used to deposit aluminum using electron-beam evaporation and also to oxidize the aluminum as will next be described. For instance, in the case of additive shadow evaporation technique, the bottom aluminum electrode is deposited in the first direction; then, the deposited metal is oxidized; finally, the wafer is rotated and the top aluminum electrode is deposited in the second direction, different from the first direction.

The dielectric thickness can be tuned through a combination of changing the oxidation conditions, e.g., oxidizing species (molecular oxygen, oxygen radicals, ozone, oxygen plasma, and various oxygen-containing gas mixtures and plasmas), oxidation time, background pressure, and plasma power, and by optionally depositing additional aluminum to be oxidized between the bottom and top electrode depositions. Finally, the patterned resist is removed in a solvent lift-off.

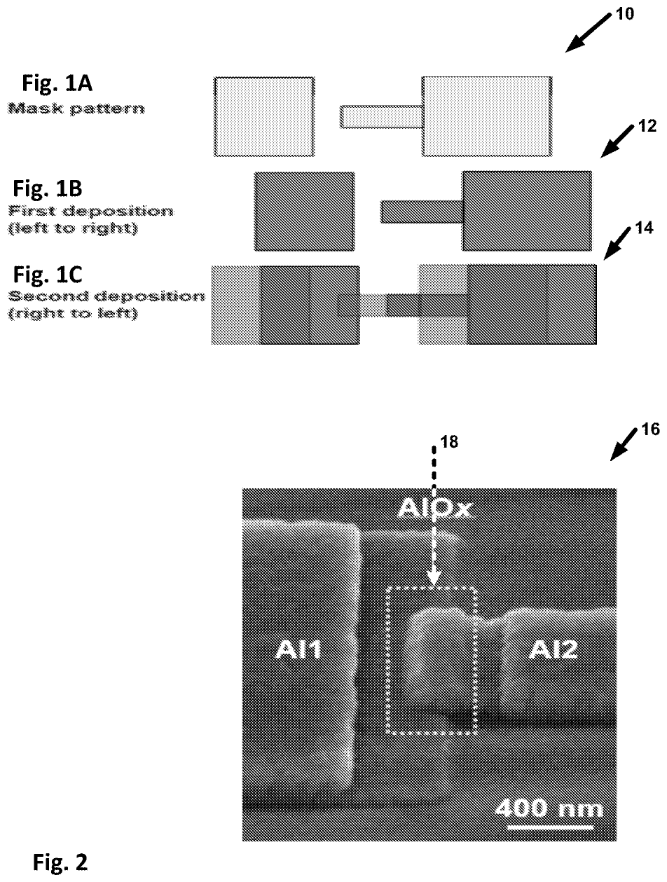

Referring now to FIGS. 1A-1C, they are a series of views illustrating a deposition process at two different deposition angles (sometimes referred to as a two-step shadow-evaporation process). FIG. 1A illustrates an example mask pattern 10 while FIG. 1B illustrates a first deposition process 12 moving in the first direction (e.g., from left-to-right) over the mask pattern. FIG. 1C illustrates the second deposition process 14 moving in the second, different direction (e.g., from right-to-left) over the mask pattern.

Referring now to FIG. 2 is an image of a shadow-evaporated parallel-plate superconducting capacitor 16 comprising an overlap region 18 formed via a mask and two-step shadow-evaporation process such as the mask and process illustrated in FIGS. 1A-1C.

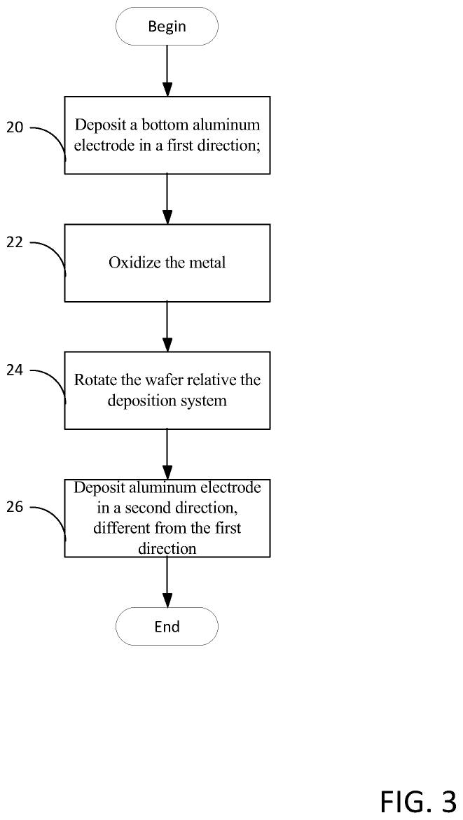

Referring now to FIG. 3 is a flow diagram of a minimal process for fabricating a shadow-evaporated device with oxide barrier for use in superconducting circuit. The process begins in processing block 20 in which a first electrode comprising a metal such as aluminum is deposited in a first direction on a substrate. The first electrode may, for example, be the first (or bottom) electrode of a capacitor. The process then proceeds to processing block 22 in which the first electrode is oxidized. Parameters of this oxidation determine the viability of this structure as a capacitor. Processing then proceeds to processing block 24 in which the substrate (e.g., a wafer) is rotated relative the deposition system. The process then proceeds to processing block 26 in which a second electrode comprising a metal such as aluminum is deposited in a second, different direction (i.e., a direction which is different relative to the first direction). The second electrode may, for example, be the second (or top) electrode of a capacitor. The particular first and second directions will depend upon the particular device being fabricated and a desired shape of one or more particular structures in the device.

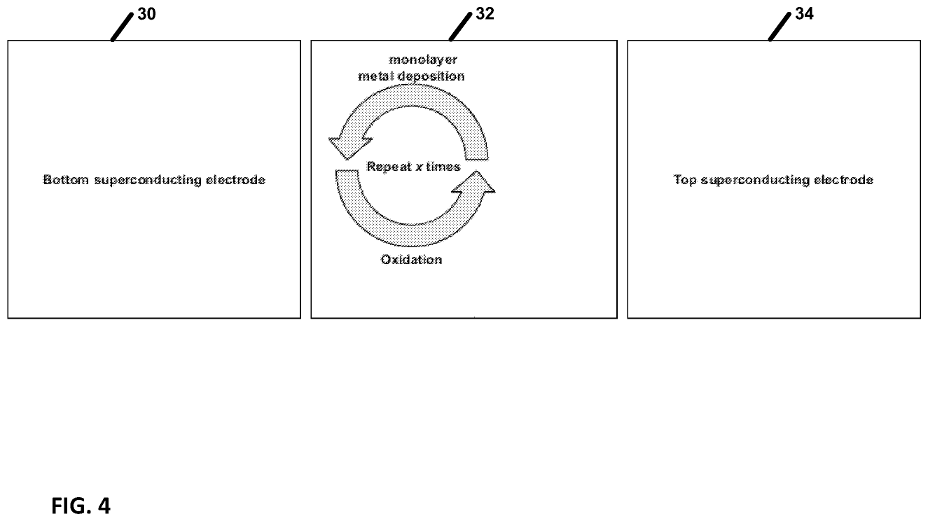

Referring now to FIG. 4 is a process flow chart of an illustrative minimum process for fabricating a superconducting device having a pair of electrodes with a dielectric between them constructed by cyclic oxidation. As shown at 30, a bottom superconducting electrode has one or more metal layers 32 deposited thereon. Metal layers are oxidized. In preferred embodiments, a first metal layer is deposited, then oxidized. A second metal layer is then deposited over the first (now oxidized) metal layer. The second metal layer is then oxidized. This deposition-oxidation process is sequentially repeated until a desired numbers of oxidized metal layers forming a oxide film are disposed over the first electrode. In embodiments, this processing occurs under vacuum with an appropriately selected controlled atmosphere which does not inhibit the deposition-oxidation process. Multiple oxidation pathways exist including, but not limited to: oxygen containing precursors, molecular oxygen, oxygen plasma, and ozone. In embodiments, the dielectric comprises shadow evaporated dielectric comprising N layers of individually oxidized aluminum. In some embodiments, all layers used to create the AlOx are oxidized. The metal layers that serve as the top and bottom plates/electrodes of the capacitor are not oxidized (e.g. the top and bottom layers may remain as metallic aluminum). In embodiments, deposited N layers of aluminum are individually oxidized. In embodiments, deposited N layers of aluminum are individually and sequentially oxidized.

Although in at least some embodiments, deposited N layers of thin aluminum are individually oxidized. It should, however, be appreciated that this is not necessary and other approaches may also be used. For example, in some embodiments it may be desirable or even necessary, to oxidize two or more layers concurrently or simultaneously. In some embodiments, it may be desirable or even necessary that one or more layers be left unoxidized. For example., in some applications such as those involving serially connected multilayer capacitors or SISIS junctions, oxidation of all aluminum layers may not be required.

In still other embodiments it may be desirable or even necessary, to oxidize two or more layers concurrently or simultaneously while leaving one or more layers unoxidized. In still other embodiments it may be desirable or even necessary, to oxidize some individual layers while leaving one or more layers unoxidized. In embodiments, the individual layers may be oxidized sequentially.

It is, of course, appreciated that the different aforementioned approaches may alter the dielectric loss tangent and device performance.

In embodiments for fabricating a PPC, 1-5 monolayer depositions of an oxidizable material may be used. For example, a metal such as aluminum may be used to provide a reactively formed oxide. A thickness of the oxide film is related to the number of times the deposition-oxidization cycle is repeated. Thus, producing a thicker oxide film may be provided by increasing the number of repetitions of the deposition-oxidization cycle (i.e., if the cycle is repeated x times, where x is an integer equal to or greater than 1) the thickness of the oxide film increases as x increases). In embodiments, each of the x individual layers of oxidized metal (e.g., oxidized aluminum) may be provided having a sub-nanometer thickness.

In embodiments, a superconducting device may be formed wherein the first and second electrodes may be provided as first and second layers of superconducting material, the dielectric (i.e., the oxide film from block 32) is disposed between and in contact with the first and second layers of superconducting material. To form a parallel-plate capacitor, the AIOx so formed, or at least a portion of that AlOx so formed, must be in contact with the metallic electrodes.

In embodiments, the dielectric may comprise N individual layers of oxidized aluminum with each of the N individual layers of oxidized aluminum having a thickness less one one-half nanometer, wherein N is an integer greater than or equal to one.

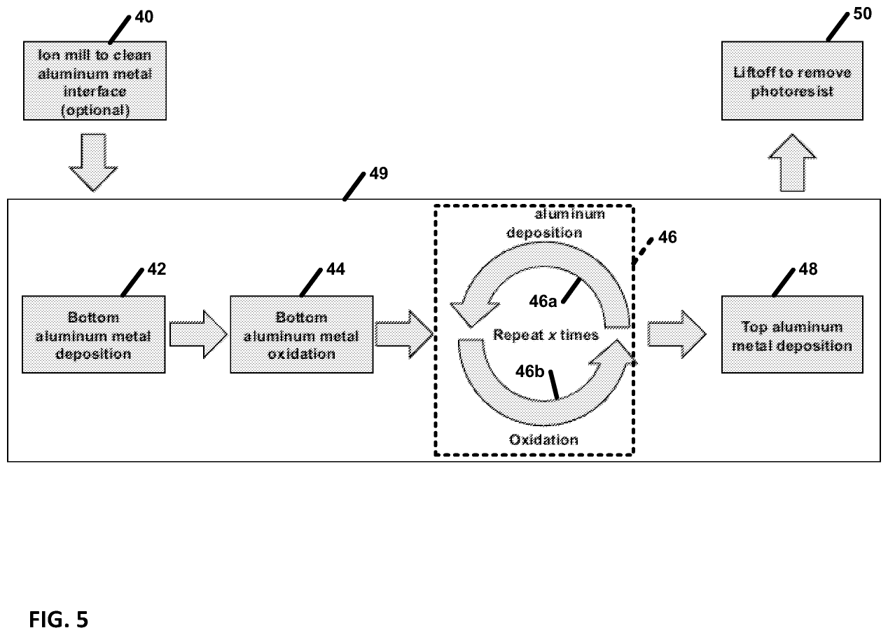

Referring now to FIG. 5 is a process flow chart of an illustrative a single lithographic process for fabricating a PPC.

In the example embodiment of FIG. 5, processing begins with optional process block 40 in which an aluminum metal interface is cleaned. This may be accomplished using an ion milling technique. Other cleaning techniques may, of course, also be used. In block 42 a first (or bottom) aluminum metal deposition is made. Processing then proceeds to block 44 in which the deposited aluminum metal is oxidized. Processing then proceeds to block 46 in which one or more metal layers (e.g., aluminum layers) are deposited 46a. In embodiments a 1-2 nm aluminum deposition may be used at 46a. The deposited metal layers (e.g,, 1-2 nm thick aluminum layers) may then be oxidized 46b.

In preferred embodiments, a first metal layer is deposited, then oxidized (i.e., process 46a is performed and then process 46b). Next, a second metal layer is then deposited over the first (now oxidized) metal layer. The second metal layer is then oxidized (i.e., processes 46a and 46b are repeated). This deposition-oxidation process may be repeated x times (where x is an integer greater than or equal to 1) until a desired numbers of oxidized metal layers which form an oxide film are disposed over the first aluminum metal provided in block 42. In this way, an oxide film is disposed over the first aluminum metal which may serve, for example, as a first electrode of a device. A thickness of the oxide film is related to the number of times the deposition-oxidation cycle is repeated. Thus, increasing the deposition-oxidation process 46 increases a thickness of the oxide film.

Processing then proceeds to block 48 in which a second aluminum metal deposition is made over a surface of the oxide film. The second aluminum metal may serve, for example, as a second electrode of a device.

In embodiments, processing in block 49 occurs under vacuum with an appropriately selected controlled atmosphere which does not inhibit the deposition-oxidation process. Multiple oxidation pathways exist including, but not limited to: oxygen containing precursors, molecular oxygen, oxygen plasma and ozone.

Processing then proceeds to block 50 in which a liftoff technique may be used to remove photoresist. Other techniques may also be used.

In embodiments. an evaporator, examples include, but are not limited to commercially available systems made by manufacturers such as Plassys, Angstrom, etc., in single-chamber, multi-chamber, or cluster tool configurations, or any custom made evaporator or deposition system may be used to deposit aluminum on a wafer using electron-beam evaporation or any other thin-film deposition method and also to oxidize the aluminum in the following manner: first the bottom aluminum electrode is deposited in the first direction; second, the metal is oxidized; third, the wafer is rotated and the top aluminum electrode is deposited in the second direction. The dielectric thickness is tuned through a combination of changing the oxidation conditions, e.g., oxidizing species (molecular oxygen, plasma oxygen, etc.), oxidation time, background pressure, and plasma power, and by optionally depositing additional aluminum to be oxidized between the bottom and top electrode depositions. Finally, the patterned resist is removed in a solvent lift-off.

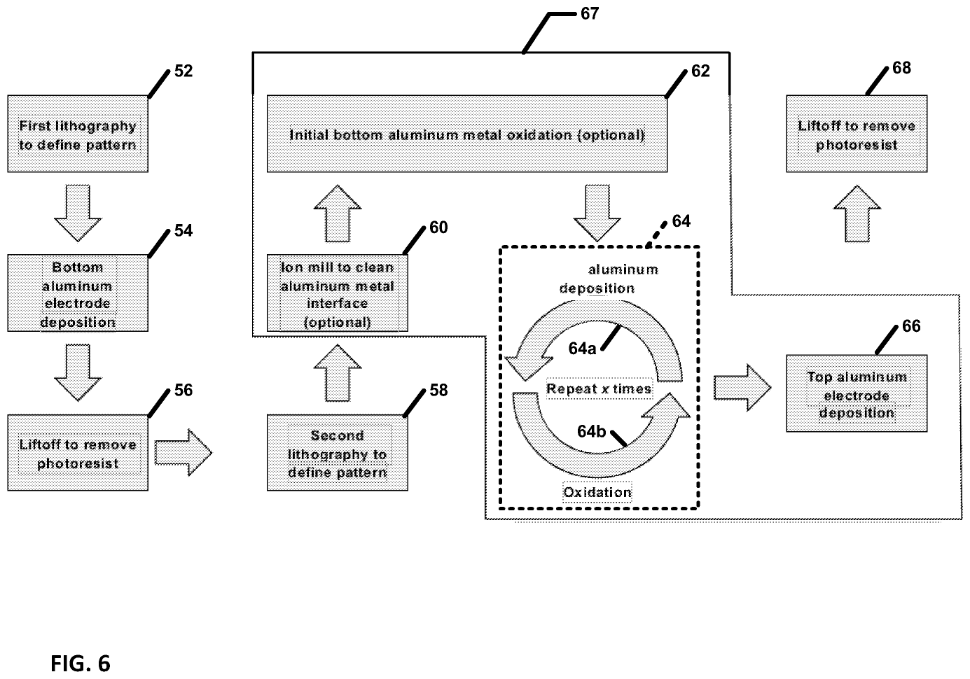

FIG. 6 is a process flow chart of an illustrative a double lithographic process.

In the example double lithographic process embodiment of FIG. 6, processing begins in block 52 in which a first lithographic pattern is defined using a lithographic process and a photoresist as is generally known. Processing then proceeds to block 54 in which a first (or bottom) aluminum electrode is deposited using a deposition process. A lift off technique is may be used to remove undesired photoresist as shown in block 56.

Processing then proceeds to block 58 in which a second lithographic pattern is defined using a lithographic process and a photoresist as is generally known. Processing may optionally proceed to block 60 in which an aluminum metal interface is cleaned. This may be accomplished using an argon ion milling technique, for example. Other cleaning techniques, e.g., argon sputter etching, may, of course, also be used.

Processing then proceeds to block 62 in which a first (or bottom) aluminum electrode is deposited using a deposition process. In embodiments, the deposited aluminum metal may be oxidized.

Processing then proceeds to block 64 in which one or more metal layers (e.g., aluminum layers) are deposited 64a. In embodiments a 1-2 nm aluminum deposition may be used at 64a. The deposited metal layers (e.g., 1-2 nm thick aluminum layers) are then oxidized 64b.

In preferred embodiments, a first metal layer may be deposited, then oxidized (i.e., process 64a may be performed follows by oxidization process 64b). Next, another metal layer may be deposited over the first (now oxidized) metal layer. The other metal layer may then be oxidized (i.e., processes 64a and 64b may be repeated). This deposition-oxidation process may be repeated any number of time (e.g., x times when x is an integer equal to or greater than 1) until a desired numbers of oxidized metal layers are formed. The desired number of oxidized metal layers (i.e., one or more oxidized metal layers) form an oxide film disposed over the first aluminum metal provided in block 62. In this way, an oxide film is disposed over the first aluminum metal which may serve, for example, as a first electrode of a device. As explained above, a thickness of the oxide film is determined by the number of times the deposition-oxidation cycle is repeated. Thus, increasing the number of times deposition-oxidation process 64 is performed increases a thickness of the oxide film.

Processing then proceeds to block 66 in which a second aluminum metal deposition is made over a surface of the oxide film. The second aluminum metal may serve, for example, as a second electrode of a device.

In embodiments, processing in block 67 occurs under vacuum with an appropriately selected controlled atmosphere which does not inhibit the deposition-oxidation process. Multiple oxidation pathways exist including, but not limited to: oxygen containing precursors, molecular oxygen, oxygen plasma and ozone.

Processing then proceeds to block 68 in which a liftoff technique may be used to remove photoresist. Other techniques may also be used.

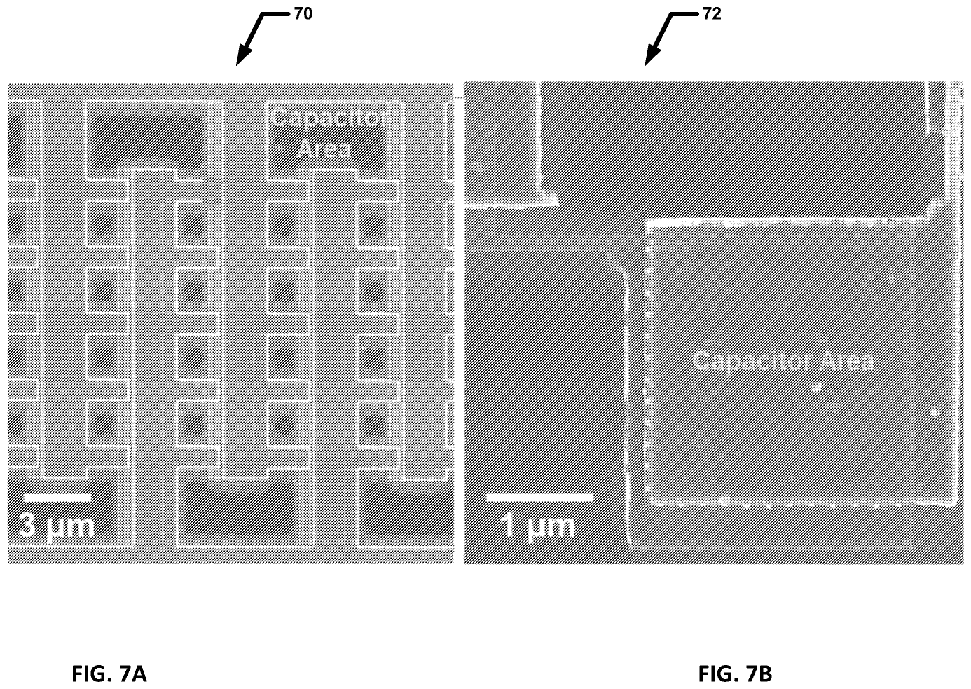

Referring now to FIGS. 7A-7B, shown are two examples 70, 72 of low loss parallel plate capacitors (LLPPC) provided using the process described herein. The LLPPC is outlined in each instance for visualization. The total capacitance, dielectric loss, feature size, and capacitor size may differ based on the chosen shadow-evaporation process, due to stray capacitances outside of the LLPPC, e.g., between separate Dolan bridges in the Dolan array shown in FIG. 7A, and differing participations of the surfaces and interfaces near the capacitor.

The several LLPPCs were characterized using room-temperature (RT) capacitance measurements as shown in Table I.

Table 1 is a summary of room-temperature electrical measurements summary from representative wafers of several processes. The specific capacitance is defined as the average of the slopes of the lines of best fit from each chip's capacitance measurements of five or nine different capacitors ranging in area from 120 μm² to 2200 μm². The cross-wafer uniformity is the normalized standard deviation of the fitted specific capacitance from each chip. The cross-chip uniformity is the average normalized standard deviation of identical test structures across the chip, except for early iterations which had only one capacitor of each size per chip. In these cases, marked with a *, the cross-chip uniformity is the normalized standard deviation of the measured capacitance of each capacitor on the chip divided by the area.

TABLE I

| Shadow- | Dielectric | | Cross-Chip | Cross-Wafer |
|---|---|---|---|---|
| Evaporation | Thickness | Cₛ | Uniformity | Uniformity |
| Process | (nm) | (fF/μm) | (%) | (%) |
| Dolan Bridge | 4.8 | 18.5 +/− 0.1 | 0.6 +/− 0.3 | 0.5 +/− 0.1 |
| Dolan Bridge | 7.0 | 12.6 +/− 0.2 | 1.1 +/− 0.5 | 1.4 +/− 0.4 |
| Dolan Bridge | 8.6 | 10.3 +/− 0.5 | 1.1 +/− 0.5 | 3.9 +/− 0.6 |
| Manhattan | 8.7 | 10.1 +/− 0.2 | 0.4 +/− 0.2 | 2.0 +/− 0.1 |

From such characterizations it may be concluded that, in embodiments, aluminum oxide films between 5 nm to 10 nm thick were grown, assuming a dielectric constant of K=10 and based on the specific capacitance as measured from room-temperature (RT) capacitance measurements. The room-temperature capacitance measurements were made at 13 MHz and 50 mV using ground-signal-ground (GSG) test structures containing a series of increasingly larger-area capacitors as determined by scanning-electron microscopy. Furthermore, in embodiments, the uniformity of the processes across a 5 mm×5 mm chip was calculated to be better than 2% and better than 4% across a 50 mm wafer. The yield for capacitors-defined as having a capacitance within 3 standard deviations of the average-on these devices was generally between 95% and 100% for the 276 test structures across each wafer. Direct current leakage measurements up to 50 mV were performed at 4 K in a liquid helium bath cryostat using the same GSG test structures, and the leakage was limited by the resolution of our tool to less than a few picoamps.

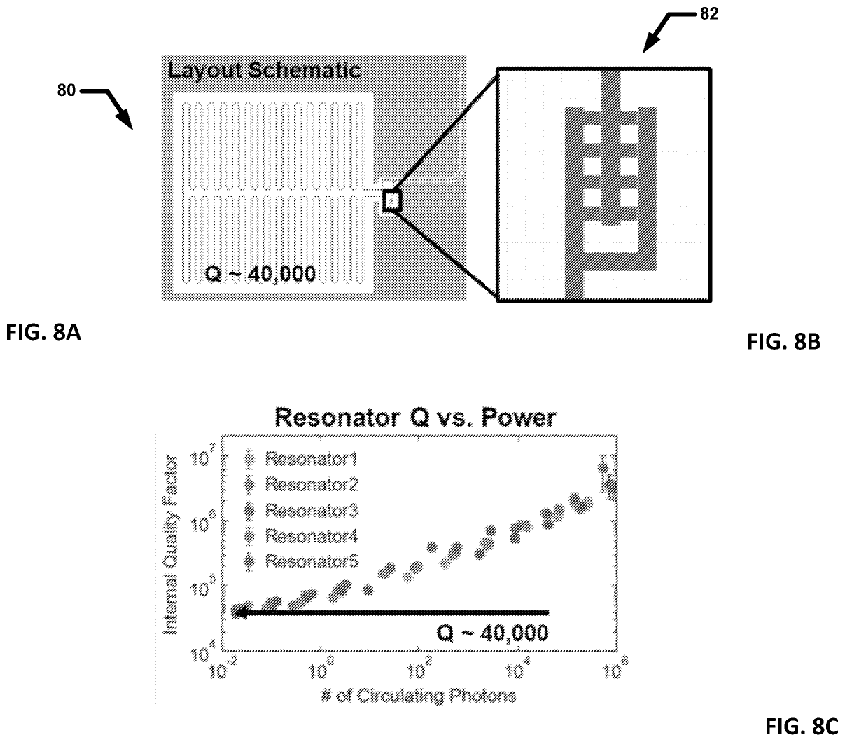

Having established the functional capacitance of these LLPPCs, the LLPPCs were characterized in lumped-element (LE) resonators as schematically represented in FIGS. 8A and 8B.

Referring now to FIGS. 8A, 8B (with FIG. 8B being an enlarged view of a portion of FIG. 8A) a 50 fF capacitance LLPPC 80 was used to match to a 16 nH aluminum meander 82 to approximate the proportion used in many qubit designs, and frequency-multiplexed six resonators to a feedline.

A similar LE resonator with a coplanar paddle capacitor (not shown) was used as a baseline.

Assuming performance is limited by dielectric loss and, moreover, in view of the discrete capacitor and meander inductor, that the participation is dominated by the discrete capacitor. Therefore, an upper bound on the quality factor of the capacitor can be establish. Indeed, in the baseline LE resonator, it was found the quality factor is on order 1M at single-photon power as expected from a typical qubit process. For the LLPPC LE resonators, it is found the quality factor at single-photon power in the '40,000 range and increasing to '1M range at high power (1M photons). No asymptote was observed in quality factor.

The LLPPC fabrication described herein is compatible with any qubit process. In embodiments, the PPC structures described were fabricated on 50 mm high-resistivity silicon substrates. The LLPPC may be fabricated with many shadow-evaporation techniques, including the Dolan-bridge process, a Manhattan-style process, and a Lecocq process. In all cases, the structure is defined by electron-beam lithography (although photolithography could be employed). As noted above, a Plassys cluster tool may be used to deposit aluminum using electron-beam evaporation and also to oxidize the aluminum in the following manner: first, the bottom aluminum electrode is deposited in the first direction; second, the metal is oxidized; third, the wafer is rotated and the top aluminum electrode is deposited in the second direction. The dielectric thickness is tuned through a combination of changing the oxidation conditions, e.g., oxidizing species (molecular oxygen, plasma oxygen, etc.), oxidation time, background pressure, and plasma power, and by optionally depositing additional aluminum to be oxidized between the bottom and top electrode depositions. Finally, the patterned resist is removed in a solvent lift-off.

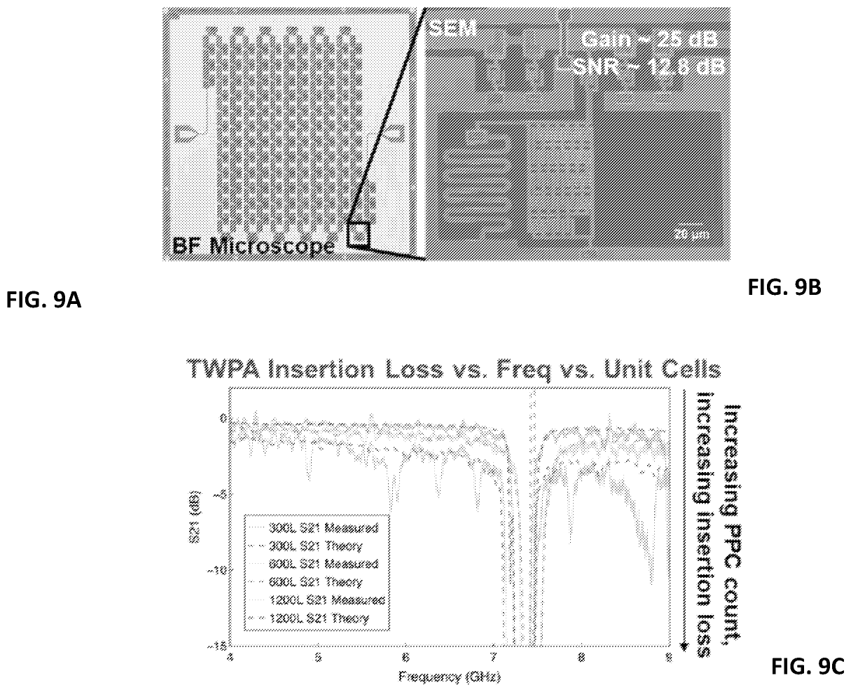

Next, an LLPPC was characterized in a Josephson TWPA (JTWPA) device, as shown in FIGS. 9A-9C.

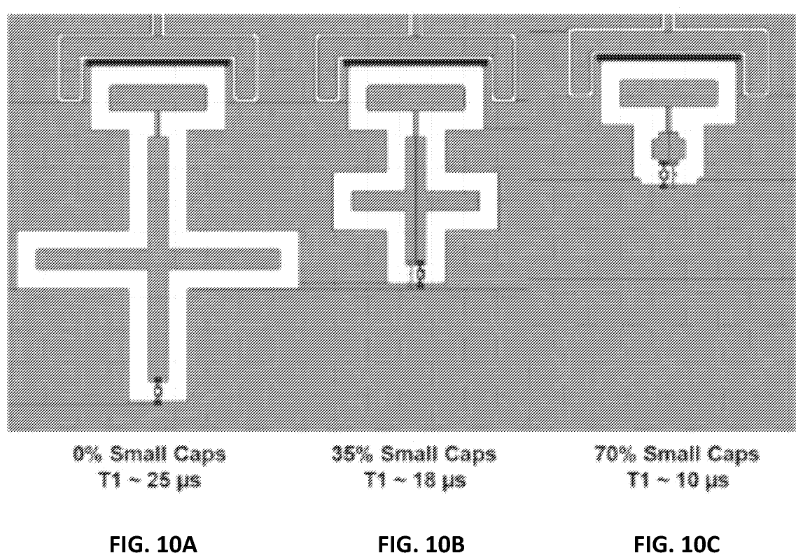

Finally, LLPPC were characterized in several flux qubits and transmons. SEM images of representative devices are shown in FIGS. 10A-10C and highlight the reduction in size possible using a LLPPC for both the coupling and shunt capacitors. As in the case of the LE resonators, a baseline qubit having no LLPPC was used, and a series of capacitors with increasing participation in the LLPPC were also used. Coherence times that decrease with increased participation in the shunt capacitor were observed as expected for a capacitor with higher loss than the coplanar capacitor. Based upon the coherence times and the varying participation, one can estimate the intrinsic loss tangent of the LLPPC, and find it to be ˜10⁻⁴, which differs from both the calculated value for the LE resonators and for the JTWPA. Again, the discrepancy is attributed to the power in the qubit.

In summary, in one aspect, described herein is a fabrication and characterization of an LLPPC using a highly uniform shadow-evaporation process that is compatible with qubit fabrication. It was found that the performance in all tested devices behaves generally as expected for a dielectric limited by TLS, which is to say that device performance decreases with the volume of the dielectric and increases with the applied power to the LLPPC. Nonetheless, the significant increase in C_{S}, relatively low-loss, and ease of fabrication position the technology favorably amongst other low-loss dielectrics and other strategies for increasing device density and complexity. Additionally, because LLPPCs have reduced sensitivity to nearby lossy dielectrics because of the very high participation concentrated in the aluminum oxide, it is anticipated the possibility of monolithic device fabrication with multiple layers of metal-dielectric stacks. For example, the LLPPC may be buried in a lossy oxide and stacked as part of a traditional multi-level metal process, enabling additional space-savings in the third dimension, beyond the significant improvement on a single plane that we demonstrate here.

The process and systems described herein find use in a wide variety of different applications. Capacitors are an integral component in many superconducting devices, including microwave kinetic inductance detectors, traveling-wave parametric amplifiers, flux qubits, transmons for gate-based quantum computers, etc., and the dielectric loss associated with the capacitors' electric fields are a significant limitation in device performance across all of these modalities.

In one aspect the techniques described herein can be for use as a low dielectric loss (tan δ<1E-4) parallel-plate capacitor in a superconducting quantum circuit. Low dielectric loss is a system requirement that ranges from tan δ<5E-3 for some applications like traveling-wave parametric amplifiers (TWPAs) to tan δ<1E-5 for gate-based superconducting qubits. Superconducting parallel-plate capacitors provided using the concepts and methods described herein are 100× less lossy than comparable superconducting parallel-plate capacitors used in TWPAs, and there is no comparable parallel-plate capacitor for superconducting qubits. Although the dielectric loss is 10-100× more lossy than coplanar capacitor alternatives, the advantages of a parallel-plate capacitor are: (1) the reduced cross-talk between qubits; (2) minimal interaction with the environment; and (3) a 100× reduction in device size due to the significantly higher capacitance density (fF/μm²).

The concepts described herein, therefore, may be used to improve the performance in TWPAs via the use of capacitors having lower loss than conventional parallel plate or co-planar capacitors. The concepts described herein also address the problem of increasing circuit size, complexity, and scaling-up issues in superconducting qubits by providing an acceptably low-loss capacitor with significantly higher capacitance density (fF/μm²).

Quantum circuit applications (e.g., superconducting qubits), which currently rely on coplanar capacitors due to their low-loss dielectrics, may benefit greatly from an increase in the capacitance density which may be achieved using the techniques and/or devices described herein. For example, the use of capacitors provided in accordance with the concepts described herein would enable the scale-up from roughly 5-50 qubits per chip to roughly 1000 qubits for a given integrated circuit (chip) size.

There are, however, two caveats: first, although the number of qubits on a given chip would increase by two or more orders of magnitudes, the performance of an individual qubit may decrease by an order of magnitude; and second, although it would be possible to put a few thousand of qubits in one circuit (chip), the circuit complexity is also limited by the number of signals that can be routed to the chip. Nevertheless, applications exist where this trade-off would be valuable including, but not limited to, annealing-based qubits.

Quantum circuit applications that rely on existing parallel-plate capacitors, like TWPAs, would directly benefit from the reduction in the loss provided by the methods, devices and concepts described herein as a systems performance increase. Furthermore, the methods, devices and concepts described herein may benefit any quantum circuit applications requiring both a low-loss dielectric and a high capacitance density. Such devices include, but are not limited to, photon detectors, isolators (including on-chip isolators), circulators (including on-chip circulators), quantum bits, parametric amplifiers, radioastronomy detectors, resonant circuits, superconducting transmission lines, and the like.

In one aspect, described is a method to make a shadow-evaporated parallel-plate superconducting capacitor using an aluminum oxide dielectric. One significant use of the method is to fabricate a low-loss, high capacitance density capacitor. It is noted, however, the described methods may have application in fabricating a non-linear inductor. Such a non-linear inductor may be defined by two superconducting aluminum layers separated by a tunably thick low-loss aluminum oxide dielectric.

One feature of the concepts, methods and devices described herein is the use of a very thin (5-15 nm) dielectric as a capacitor. While perhaps unsuitable for some high power applications (due to a low breakdown voltage and breakdown charge), it is well-suited for use in applications having low power requirements for experiments in a dilution fridge such that the breakdown voltage is not exceeded. Furthermore, devices provided in accordance with the methods and concepts described herein may generate some pseudo-Josephson inductance due to the very thin dielectric. It is, however, noted that in the applications discussed herein, such inductance may be dominated by Josephson junctions, and the additional inductance from devices provided in accordance with the concerts described herein, is small in comparison and is simply another design input with small (and ideally, minimal) deleterious effects in the device.

In yet another aspect, described is a process by which a low loss dielectric may be formed, which is critical in establishing its low-loss property and for its tunable thickness. The inventors have discovered that a tunably thick dielectric can be fabricated using a multi-angle deposition process with a shadow mask-a shadow evaporation process. It should, however, be appreciated that described methods are not limited to any single type of shadow evaporation (e.g., Dolan bridge, Manhattan, Lecocq.

It should also be appreciated that other additive techniques, including by not limited to aluminum deposition by magnetron sputtering, electron beam evaporation, and thermal evaporation, may also be used. In some embodiments, the structure can be defined by electron-beam lithography (although photolithography could be employed). An evaporator, examples include, but are not limited to those made by manufacturers such as Plassys, Angstrom, etc., in a single-chamber, multi-chamber, cluster tool, or other configurations, can then be used to deposit aluminum using electron-beam evaporation and also to oxidize the aluminum as will next be described. For instance, in the case of additive shadow evaporation technique, the bottom aluminum electrode is deposited in the first direction; then, the deposited metal is oxidized; finally, the wafer is rotated and the top aluminum electrode is deposited in the second direction, different from the first direction.

It should also be appreciated that subtractive processes (e.g., subtractive techniques utilizing deposit and etch processes) may also be used, although depending on the fabrication steps may incur higher loss. For example, it should be appreciated that subtractive processes may also be used to create AlOx capacitors, by growing the dielectric first and then etching. However, subtractive processes may involve more fabrication steps than the shadow evaporation process described herein or other additive techniques and thus subtractive techniques may, although not necessarily, lead to more loss.

Although Josephson junctions (JJ) having thin dielectrics (˜1 nm) are formed using shadow evaporation, that process includes reactively oxidizing exposed surface metal.

In contrast, the process described herein differs form a conventional process in at least two ways: first, using shadow evaporation to pattern a parallel-plate capacitor; and second, forming the thick dielectric using a cyclical process of reactively oxidizing the aluminum surface and then depositing a thin layer (e.g., a layer having a subnanometer thickness such as a thickness of about 0.5 nm) of additional metal on top of the reactively formed oxide, which is then consumed in an additional process of reactively oxidizing. The cyclical process of metal deposition and reactively oxidizing deposited metal is done with the same shadow mask and without breaking vacuum, and the thickness of the dielectric—and, therefore, the specific capacitance and inductance—increases with the number of cycles.

The concepts described herein are applicable to basic circuit elements, the concepts have a wide range of applications.

One advantage provided by the processes, devices and concepts described herein is the use of a low-loss dielectric in a capacitor, as defined by the loss tangent of the dielectric. The loss tangent may be about 100× higher than comparable parallel-plate capacitors and is a significant feature that enables its use in superconducting circuits. One limitation is that the loss tangent is still about 10× lower than coplanar capacitors, such that a design choice must be made between highest performance (lowest loss tangent) and highest device density (highest specific capacitance).

Various embodiments of the concepts, systems, devices, structures and techniques sought to be protected are described herein with reference to the related drawings. Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the claims and the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs. The terms “one or more” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection”.

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal, “top,” “bottom,” and derivatives thereof shall relate to the described structures and methods, as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted that the term “selective to, “such as, for example, “a first element selective to a second element,” means that the first element can be etched and the second element can act as an etch stop.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways. Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

What is claimed is:

1. A superconducting device comprising:
first and second layers of superconducting material; and
a dielectric disposed between and in contact with the first and second layers of superconducting material, the dielectric comprising N individual layers of oxidized aluminum with each of the N individual layers of oxidized aluminum having a sub-nanometer thickness, where N is an integer greater than or equal to one.

2. The superconducting device of claim 1 wherein the dielectric comprises a shadow evaporated dielectric comprising N layers of an oxidized metal.

3. The superconducting device of claim 2 wherein the shadow evaporated dielectric comprises N layers of individually oxidized aluminum.

4. The superconducting device of claim 1 wherein the device is a parallel-plate superconducting capacitor.

5. The superconducting device of claim 1 wherein a thickness of the aluminum oxide dielectric is selected such that the device has characteristics of a parallel-plate superconducting capacitor.

6. The superconducting device of claim 1 wherein the device is a non-linear inductor.

7. The superconducting device of claim 1 wherein a thickness of the aluminum oxide dielectric is selected such that the device has characteristics of a non-linear inductor.

8. A device comprising:
a substrate having first and second opposing surfaces;
a first superconducting aluminum layer disposed on a first surface of the substrate;
an oxide film disposed over the first superconducting aluminum layer; and
a second superconducting aluminum layer disposed over the oxide film.

9. The device of claim 8 wherein the oxide film comprises N layers of individually oxidized metal where N is an integer greater than 1.

10. The device of claim 9 wherein the N layers of individually oxidized metal comprise N layers of an aluminum oxide dielectric.

11. The device of claim 8 wherein a thickness of the oxide film is selected to provide the device as one of a parallel plate capacitor or an LE inductor.

12. The device of claim 8 wherein a surface of the first superconducting aluminum layer is oxidized.

13. The device of claim 8 wherein the substrate comprises a wafer.

14. The device claim 9 wherein a thickness of the two superconducting aluminum layers and N aluminum oxide dielectric layers are selected so as to provide the device having a low-loss, high capacitance density capacitor characteristic.

15. The device claim 9 wherein a thickness of the two superconducting aluminum layers and N aluminum oxide dielectric layers are selected so as to provide the device having a non-linear inductor characteristic.

16. A shadow-evaporated parallel-plate superconducting capacitor comprising:
first and second layers of superconducting material; and
a dielectric disposed between the first and second layers of superconducting material.

17. The shadow-evaporated parallel-plate superconducting capacitor of claim 16 wherein the first and second layers of superconducting material comprise two superconducting aluminum layers.

18. The shadow-evaporated parallel-plate superconducting capacitor of claim 16 wherein the dielectric comprises an aluminum oxide dielectric.

19. The shadow-evaporated parallel-plate superconducting capacitor of claim 18 wherein the aluminum oxide dielectric comprises N layers of individually oxidized aluminum wherein N is an integer greater than or equal to one.

20. The shadow-evaporated parallel-plate superconducting capacitor of claim 19 wherein each of the N layers of individually oxidized aluminum has a sub-nanometer thickness.

21. A method comprising:
(a) depositing a first electrode on a substrate;
(b) oxidizing the first electrode to provide a first oxidized electrode;
(c) depositing N layers of metal over the first oxidized electrode wherein N is an integer equal to or greater than 1 and wherein the N layers of metal are individually and sequentially deposited and at least some of the metal layers are oxidized to provide a dielectric comprising one or more oxidized metal layers and wherein a thickness of the dielectric is determined by the number N; and
(d) depositing a second electrode over the dielectric.

22. The method of claim 21 wherein depositing N layers of metal comprises depositing N layers of metal with each of the N layers of metal having a sub-nanometer thickness.

23. The method of claim 21 wherein depositing N layers of metal comprises depositing N layers of aluminum with each of the N layers of aluminum having a sub-nanometer thickness.

24. The method of claim 21 wherein depositing N layers of metal over the first oxidized electrode wherein N is an integer equal to or greater than 1 and wherein the N layers of metal are individually and sequentially deposited and oxidized to provide a dielectric comprising N oxidized metal layers and wherein a thickness of the dielectric is determined by the number N of individual metal oxide layers

25. The method of claim 21 wherein depositing N layers of metal comprises depositing N layers of aluminum and wherein at least some of the N layers of aluminum are individually and sequentially deposited and oxidized.

26. The method of claim 21 wherein depositing N layers of metal comprises depositing N layers of aluminum and wherein each of the N layers of aluminum are individually and sequentially deposited and oxidized to provide a dielectric comprising N layers of aluminum oxide (AlOx) and wherein a thickness of the AlOx dielectric is determined by the number N of individual aluminum metal oxide layers.

27. The method of claim 21 wherein depositing N layers of metal comprises depositing N layers of aluminum and wherein at least some of the N layers of aluminum are individually and sequentially deposited and oxidized to provide a dielectric comprising N layers of aluminum oxide (AlOx) and wherein a thickness of the AlOx dielectric is determined by the number N of individual aluminum metal oxide layers.
